(19) United States
(12) Patent Application Publication
(10) Pub. No.: US 2014/0261658 A1
(43) Pub. Date: Sep. 18, 2014

(54) ORGANIC SOLAR CELL

(71) Applicant: National Tsing Hua University, Hsinchu City (TW)

(72) Inventors: Hao-Wu LIN, Zhubei City (TW); Yi-Hong CHEN, Taichung City (TW); Cheng-Yu HUANG, Taipei City (TW)

(21) Appl. No.: 13/922,664

(22) Filed: Jun. 20, 2013

(30) Foreign Application Priority Data
Mar. 15, 2013 (TW) 102109356

(51) Int. Cl. H01L 51/44

(52) U.S. Cl. CPC H01L 51/44
USPC 136/256; 136/263

(57) ABSTRACT

An organic solar cell includes a conductive substrate, an organic material, and two metal layers. The conductive substrate includes an electrode. The organic material is disposed above the conductive substrate. The metal layers are disposed above the organic material, and a gap is configured between the two metal layers. The width of the gap is between 1 nm and 5000 nm.

### CROSS REFERENCE TO RELATED APPLICATIONS

This Non-provisional application claims priority under 35 U.S.C. §119(a) on Patent Application No(s). 102109356 filed in Taiwan on Mar. 15, 2013, the entire contents of which are hereby incorporated by reference.

### BACKGROUND OF THE INVENTION

1. Field of Invention

The present disclosure relates to an organic solar cell.

2. Related Art

For the sake of environmental protections, the green power sources have become the most popular topic in the recent researches. In particular, the solar cell technology, which is capable of generating electricity by absorbing solar light, is considered as one of the most potential technologies, and many researches have discussed about solar cells.

The color solar cells are major the color dye-sensitized solar cells, which may have different colors by selecting the proper dye of desired color. In the recent years, the building integrated photovoltaic (BIPV), which integrates the photovoltaic components to the building materials for constructing a specific building, has become more and more popular. The BIPV components not only have the power generation function, but also can construct a part of the building (external parts). Thus, they can substitute the conventional building materials to reduce the cost thereof, and further improve the power saving efficiency with combining some proper designs such as the shielding design and usage of ambient light. The colorful solar cells are therefore particularly suitable for this application to make the building more beautiful.

However, the color of the color dye-sensitized solar cells is changed by using different dye materials. Otherwise, varied dye materials are made of different synthesizing methods, and moreover, the components and manufacturing processes of the color dye-sensitized solar cell should be modified. These modification and changes make the manufacturing processes more complex and expensive. Besides, the dyes with different colors may results in non-equivalent power conversion efficiency. If a rare color is needed, it is difficult to find a proper dye material so that the power conversion efficiency may further reduced.

Therefore, it is an important subject of the present disclosure to provide an organic solar cell with adjustable color that has lower manufacturing cost and simplified manufacturing processes.

### SUMMARY OF THE INVENTION

In view of the foregoing subject, an objective of the present disclosure is to provide an organic solar cell with adjustable color that has lower manufacturing cost and simplified manufacturing processes.

To achieve the above objective, the present disclosure discloses an organic solar cell including a conductive substrate, an organic material, and two metal layers. The conductive substrate includes an electrode. The organic material is disposed above the conductive substrate. The metal layers are disposed above the organic material, and a gap is configured between the two metal layers. The width of the gap is between 1 nm and 5000 nm.

In one embodiment of the disclosure, the electrode is a transparent electrode.

In one embodiment of the disclosure, the material of the metal layers comprises silver, gold, aluminum, or their combinations.

In one embodiment of the disclosure, the thickness of the metal layers is between 5 nm and 80 nm.

In one embodiment of the disclosure, the organic solar cell further includes a spacer layer disposed within the gap, and the spacer layer is light-permeable.

To achieve the above objective, the present disclosure also discloses an organic solar ell including a conductive substrate, an organic material and two metal layers. The conductive substrate includes an electrode. The organic material is disposed above the conductive substrate, and the two metal layers are disposed above the organic material. A gap is configured between the two metal layers, and the thickness of the two metal layers is between 5 nm and 80 nm.

In one embodiment of the disclosure, the electrode is a transparent electrode.

In one embodiment of the disclosure, the material of the metal layers comprises silver, gold, aluminum, or their combinations.

In one embodiment of the disclosure, the width of the gap is between mm and 5000 nm.

In one embodiment of the disclosure, the organic solar cell further includes a spacer layer disposed within the gap, and the spacer layer is light-permeable.

As mentioned above, the width of the spacer layer (or the distance between two metal layers) of the disclosure can be changed so as to modify the wavelength of the light outputted from the organic solar cell, thereby changing the color of the emitted light. Accordingly, the manufacturing cost of the organic solar cell can be decreased, and the manufacturing processes thereof can be simplified. Besides, the thicknesses of the two metal layers can adjusted so as to obtain the emitted light with higher purity.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic diagram showing an organic solar cell according to an embodiment of the disclosure;

FIG. 2A is a schematic diagram showing an organic solar cell according to an experimental embodiment of the disclosure;

FIG. 2B is a graph diagram showing the wavelengths capable of transmitting the organic solar cell under different spacer layer thicknesses;

FIG. 3 is a schematic diagram showing an organic solar cell according to another embodiment of the disclosure; and

FIG. 4 is a graph diagram showing the transmission ratio of the organic solar cell under different spacer layer thicknesses.

### DETAILED DESCRIPTION OF THE INVENTION

The present invention will be apparent from the following detailed description, which proceeds with reference to the accompanying drawings, wherein the same references relate to the same elements.

FIG. 1 is a schematic diagram showing an organic solar cell 1 according to an embodiment of the disclosure. Referring to FIG. 1, the organic solar cell 1, also named as organic photovoltaic (OPV) cell, includes a conductive substrate 11, an organic material 12 and two metal layers 13. The organic solar cell 1 can be an organic thin-film solar cell or an organic dye-sensitized solar cell, such as an organic dye-sensitized polymer or small molecular solar cell. Hereinafter, the organic solar cell 1 is an organic dye-sensitized solar cell for example.

The conductive substrate 11 has an electrode 111. To satisfy the requirements of BIPV applications or products, the conductive substrate 11 has a transparent substrate that is light-permeable. The conductive substrate 11 may be made of glass substrate or flexible plastic substrate. The electrode 111 of the conductive substrate 11 is a transparent electrode, which is made of ITO for example. For different requirements of BIPV applications or products, the conductive substrate 11 may be made of opaque. Moreover, the conductive substrate 11 is flexible, so that the size and weight of the product can be decreased and the flexible conductive substrate 11 can be applied to other flexible electrical products.

The organic material 12 has the property of absorbing light and then generating electricity. The organic material 12 can be made of small molecular material, polymer material, the combination of small molecular and polymer materials, or the combination of polymer material and organic/inorganic material. The organic material 12 is disposed above the conductive substrate 11. Herein, the organic material 12 is disposed “above” the conductive substrate 11 means that the organic material 12 is disposed directly on the conductive substrate 11, or an additional material is interposed between the organic material 12 and the conductive substrate 11.

The two metal layers 13 are disposed above the organic material 12. The material of the metal layers 13 is silver, gold, aluminum, or their combinations, and the thicknesses X₁ and X₂ thereof are between 5 nm and 80 nm, so that the metal layers 13 are light-permeable. Herein, the thicknesses X₁ and X₂ of the metal layers 13 can be the same or different. In this embodiment, the thicknesses X₁ and X₂ of the metal layers 13 are the same. The electrode 111 of the conductive substrate 11 is an anode, while one of the metal layers 13 closer to the organic material 12 is a cathode.

A gap is configured between two metal layers 13 to form a metal resonance chamber, and the width H₁ of the gap is between 1 nm and 5000 nm. A wave with a specific wavelength can have resonance in the resonance chamber, so that the density of photons with different modes is rearranged inside the organic solar cell 1. Accordingly, only a part of the light with a specific wavelength matching the optical length of the resonance chamber can be emitted from the organic solar cell 1. Regarding to the conduction of electromagnetic waves, since the electromagnetic wave has the skin depth effect with respect to metal, the gap can be designed with a width slightly larger than the resonance length, which is called the micro-cavity theory.

In practice, the gap can be filled with other materials or not (only air remained). When the gap is not filled with any material, a frame glue is formed around the edge of the two metal layers 13, and the gap between the two metal layers contains air. As shown in FIG. 1, a spacer layer 14 is disposed in the gap between the metal layers 13. The spacer layer 14 can be made of any light-permeable material such as a polymer material, small molecular material, or other light-permeable compounds. The proper polymer material is, for example, polymethylmethacrylate (PMMA), polyethylene terephthalate (PET), polyvinyl chloride (PVC), or polystyrene (PS). The small molecular material is, for example, BCP (2,9-dimethyl-4,7-diphenyl-1,10-phenanthroline), Bphen (4,7-diphenyl-1,10-phenanthroline), TmPyPB (1,3,5-tri[(3-pyridyl)-phen-3-yl]benzene), TPBi (2,2′,2″-(1,3,5-benzinetriyl)-tris(1-phenyl-1-H-benzimidazole)), TAPC (Di-[4-(N,N-ditolyl-amino)-phenyl]cyclohexane), or HAT-CN (Dipyrazino[2,3-f:2′,3′-h]quinoxaline-2,3,6,7,10,11-hexacarbonitrile). The light-permeable compound is, for example, MoO₃, ZnO, NiO, WO₃, V₂O₅, Al2O₃, SiO, SiO₂, MgO, MgF₂, CaF₂, LiF, or CsF.

FIGS. 2A and 2B show an experimental example of the organic solar cell, wherein FIG. 2A is a schematic diagram showing the structure of the organic solar cell, and FIG. 2B is a graph diagram showing the wavelengths versus the transmission ratio under different spacer layer thicknesses. In the organic solar cell 2, an electrode 211, a hole transport layer 221, an anode buffer layer 222, a donor layer 223, a mixed layer 224, an acceptor layer 225, a cathode buffer layer 226, and a spacer layer 24 are sequentially disposed on the conductive substrate 21. Herein, the electrode 211 is made of ITO and serves as an anode, the hole transport layer 221 is made of PEDOT:PSS (poly(3,4-ethylene dioxythiophene):polystyrene sulfonate), the anode buffer layer 222 is made of MoO₃, the donor layer 223 is made of DTDCPB, the mixed layer 224 is composed of DTDCPB and C70 (in volume ratio 1:1.6), the acceptor layer 225 is made of C70 derivates (fullerene-based derivates), the cathode buffer layer 226 is made of 4,7-Diphenyl-1,10-phenanthroline (Bphen), and the spacer layer 24 is disposed between two metal layers 23 (silver layers) and made of NPB (N,N′-Bis-(1-naphthalenyl)-N,N′-bis-phenyl-(1,1′-biphenyl)-4,4′-diamine). The metal layers 23 (silver layers) and the spacer layer 24 construct a metal resonance chamber, while one of the metal layers (silver layers) closer to the cathode buffer layer 226 also serves as a cathode. The thicknesses of all layers in the organic solar cell 2 are determined as shown in FIG. 2A, while the spacer layer 24 containing organic small molecules NPB has different thicknesses (nm). In addition, the activated layer of the organic solar cell 2 is composed of the donor layer 223, the mixed layer 224 and the acceptor layer 225. Otherwise, the activated layer may only contain a mixed layer 224 (mixing DTDCPB and C70) so as to form a single layer structure with mixed heterojunction. Alternatively, the activated layer may be composed of two layers including the donor layer 223 and the acceptor layer 225. To be noted, the above mentioned materials and structures are for illustrations only and are not to limit the scope of the invention.

Referring to FIG. 2B, as the thickness of the spacer layer 24 changes, the distance between the two metal layers 23 is varied accordingly, thereby adjusting the wavelength peak capable of transmitting the organic solar cell 2. When the width H₂ of the spacer layer 24 increases (e.g. from 60 nm to 140 nm), the wavelength peak capable of transmitting the organic solar cell 2 is changed from about 430 nm (purple blue) to 520 nm (green) and then reaches approximate 670 nm (red). This result indicates that the change of the distance between the two metal layers 23 (width H₂ of the spacer layer 24) can alter the wavelength capable of transmitting the organic solar cell 2. Accordingly, the organic solar cells 2 with the spacer layers 24 of different widths allow the users to view different colors.

The experimental results of the widths H₂ versus PCE (power conversion efficiency) of the organic solar cell 2 shown in FIG. 2A are shown in the following table.

| Width (nm) | 60 | 70 | 80 | 90 | 100 | 110 | 120 | 140 |
|---|---|---|---|---|---|---|---|---|
| PCE (%) | 4.20 | 5.15 | 4.58 | 4.77 | 4.92 | 4.97 | 4.93 | 4.75 |

Referring to the above table, as the widths H₂ changes, the PCE is remained around 5%. In other words, the PCE is not affected by the width H₂ and can be kept above 4.7%.

To be noted, regarding to the change of the width of the spacer layer 24, the thickness thereof and the wavelength capable of transmitting the organic solar cell 2 have the following relationship of:

D=[(2N−1)/4]×(W/n)

Herein, D represents the width of the spacer layer, N is a positive integer, W represents the wavelength (nm) of light, and n represents the refractive index of the medium material in the gap (or the material of the spacer layer). For example, assuming that the desired wavelength W of the organic solar cell is 620 nm (red), and the medium is air (refractive index=1), when N is 1, 2, and 3, the calculated width D of the spacer layer is respectively 155 nm, 465 nm, and 775 nm. In other words, when the medium is air and the desired emitted light is red (650 nm), the width D of the spacer layer can be 155 nm, 465 nm, or 775 nm. Accordingly, it is possible to manufacture an organic solar cell with different color by properly designing the width of the spacer layer.

FIG. 3 is a schematic diagram showing another organic solar cell 3 according to another embodiment of the disclosure. Referring to FIG. 3, the organic solar cell 3 includes a conductive substrate 31, an organic material 32 and two metal layers 33. In more details, the conductive substrate 31 has an electrode 311. The organic material 32 is disposed above the conductive substrate 31. The two metal layers 33 are disposed above the organic material 32. A gap is configured between the two metal layers 33, and the thicknesses Y₁ and Y₂ of the two metal layers 33 are between 5 nm and 80 nm.

Different from the previous embodiment, the organic solar cell 3 of this embodiment has a gap between two metal layers 33 with a fixed distance, while the thicknesses of the metal layers 33 are changeable for altering the FWHM of the light transmitting through the organic solar cell 3. The thicknesses Y₁ and Y₂ of the two metal layers 33 can be the same or different. In this embodiment, the thicknesses Y₁ and Y₂ of the two metal layers 33 are the same for example. The descriptions of other elements such as the conductive substrate 31, electrode 311, organic material 32, width H₂ and spacer layer 34 are the same as those illustrated in the previous embodiment, so they will be omitted hereinafter.

FIG. 4 is a graph diagram showing the transmission ratio of the organic solar cell 3 (FIG. 3) under different spacer layer thicknesses. The curves from the outside to the inside respectively represent the different thicknesses of the metal layers increased from 15 nm to 60 nm. As shown in FIG. 4, the width H₂ of the gap is fixed at 100 nm, and the FWHM values of the spectrums becomes narrower as the thicknesses Y₁ and Y₂ of the two metal layers 33 increase. In other words, as the thicknesses Y₁ and Y₂ of the two metal layers 33 become thinner, the FWHM values of the spectrums are wider so the purity of the emitted light is lower. Otherwise, as the thicknesses Y₁ and Y₂ of the two metal layers 33 become thicker, the FWHM values of the spectrums are narrower so the purity of the emitted light is higher and the color is sharper.

In summary, the width of the spacer layer (or the distance between two metal layers) of the disclosure can be changed so as to modify the wavelength of the light outputted from the organic solar cell, thereby changing the color of the emitted light. Accordingly, the manufacturing cost of the organic solar cell can be decreased, and the manufacturing processes thereof can be simplified. Besides, the thicknesses of the two metal layers can adjusted so as to obtain the emitted light with higher purity.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. An organic solar cell, comprising:
a conductive substrate comprising an electrode;
an organic material disposed above the conductive substrate; and
two metal layers disposed above the organic material, wherein a gap is configured between the two metal layers, and the width of the gap is between 1 nm and 5000 nm.

2. The organic solar cell of claim 1, wherein the electrode is a transparent electrode.

3. The organic solar cell of claim 1, wherein the material of the metal layers comprises silver, gold, aluminum, or their combinations.

4. The organic solar cell of claim 1, wherein the thickness of the metal layers is between 5 nm and 80 nm.

5. The organic solar cell of claim 1, further comprising:
a spacer layer disposed within the gap, wherein the spacer layer is light-permeable.

6. An organic solar cell, comprising:
a conductive substrate comprising an electrode;
an organic material disposed above the conductive substrate; and
two metal layers disposed above the organic material, wherein a gap is configured between the two metal layers, and the thickness of the two metal layers is between 5 nm and 80 nm.

7. The organic solar cell of claim 6, wherein the electrode is a transparent electrode.

8. The organic solar cell of claim 6, wherein the material of the metal layers comprises silver, gold, aluminum, or their combinations.

9. The organic solar cell of claim 6, wherein the width of the gap is between him and 5000 nm.

10. The organic solar cell of claim 6, further comprising:
a spacer layer disposed within the gap, wherein the spacer layer is light-permeable.
